(19) United States
(12) Patent Application Publication
(10) Pub. No.: US 2021/0104664 A1
(43) Pub. Date: Apr. 8, 2021

(54) RESISTIVE SWITCHING DEVICE HAVING CONTROLLED FILAMENT FORMATION

(71) Applicant: International Business Machines Corporation, Armonk, NY (US)

(72) Inventors: Alexander Reznicek, Troy, NY (US); Soon-Cheon Seo, Glenmont, NY (US); Choonghyun Lee, Rensselaer, NY (US); Injo Ok, Loudonville, NY (US)

(21) Appl. No.: 16/590,513

(22) Filed: Oct. 2, 2019

(51) Int. Cl. H01L 45/00; H01L 27/24

(52) U.S. Cl. CPC H01L 45/08; H01L 45/1253; H01L 27/2481; H01L 45/146; H01L 45/1683; H01L 45/1233

(57) ABSTRACT

Embodiments of the invention are directed to an integrated circuit structure that includes a resistive switching device (RSD). The RSD includes a bottom electrode, an insulator region, and a top electrode. The insulator region includes a filament region and is communicatively coupled to the bottom electrode. The top electrode is communicatively coupled to the insulator region. The filament region includes an apex region having a first apex region sidewall and a second apex region sidewall that intersects the first apex region sidewall at an angle that is less than about 90 degrees.

### BACKGROUND

The present invention relates in general to electronic storage elements/cells. More specifically, the present invention relates to fabrication methods and resulting structures for resistive switching device (RSD) storage elements configured and arranged to provide improved control over filament formation in the resistive storage/switching element (e.g., a metal oxide region) of the RSD.

Resistive random access memory (RRAM) is a nano-scale non-volatile memory (NVM). RRAM provides simple storage cell components, high density, low power, large endurance, fast write/read/erase speeds, and excellent scalability. A typical RRAM storage cell is two-terminal device formed as a metal-insulator-metal (MIM) structure (also known as an RSD). The insulator material can be a binary metal oxide, which makes the MIM/RSD storage cell compatible with silicon-based CMOS (complementary metal oxide semiconductor) fabrication process.

When a sufficient electrical field or signal is applied across the metal electrodes of a MIM, the resistance of the insulator can be switched from one resistance state to another through various mechanisms, including the formation and rupture of conductive filaments in the metal oxide. The insulator retains its resistance state until an appropriate electrical signal is applied across the MIM metal electrodes to change it.

### SUMMARY

Embodiments of the invention are directed to an integrated circuit structure that includes a RSD having a bottom electrode, an insulator region, and a top electrode. The insulator region includes a filament region and is communicatively coupled to the bottom electrode. The top electrode is communicatively coupled to the insulator region. The filament region includes an apex region having a first apex region sidewall and a second apex region sidewall. The second apex region sidewall intersects the first apex region sidewall at an angle that is less than about 90 degrees.

Embodiments of the invention are directed to an integrated circuit structure that includes a RSD having a bottom electrode, an insulator region, and a top electrode. A portion of the bottom electrode is within a via formed in a fill material of the IC structure. The insulator region includes a filament region and is communicatively coupled to the bottom electrode. The top electrode is communicatively coupled to the insulator region. The filament region includes an apex region having a first apex region sidewall and a second apex region sidewall. The second apex region sidewall intersects the first apex region sidewall at an angle that is less than about 90 degrees. At least a portion of the apex region is over the via.

Embodiments of the invention are directed to a method of forming an integrated circuit structure. A non-limiting example of the method includes forming a RSD by forming a bottom electrode, an insulator region, and a top electrode. The insulator region includes a filament region and is communicatively coupled to the bottom electrode. The top electrode is communicatively coupled to the insulator region. Forming the insulator region includes forming the filament region to include an apex region having a first apex region sidewall and a second apex region sidewall. The second apex region sidewall intersects the first apex region sidewall at an angle that is less than about 90 degrees.

Additional features and advantages are realized through techniques described herein. Other embodiments and aspects are described in detail herein. For a better understanding, refer to the description and to the drawings.

### BRIEF DESCRIPTION OF THE DRAWINGS

The subject matter which is regarded as embodiments is particularly pointed out and distinctly claimed in the claims at the conclusion of the specification. The foregoing and other features and advantages of the embodiments are apparent from the following detailed description taken in conjunction with the accompanying drawings in which:

FIG. 1A depicts a simplified block diagram illustrating a cross-sectional view of a two-terminal resistive switching device (RSD), which can be used as a storage cell of an RRAM structure capable of incorporating aspects of the invention;

FIG. 1B depicts a diagram of an I-V curve illustrating the switching operation of the RSD shown in FIG. 1A;

FIG. 2 depicts a simplified block diagram illustrating how the RSD shown in FIG. 1A can be utilized as an addressable cross-point storage cell of an RRAM crossbar array capable of incorporating aspects of the invention;

FIG. 3 depicts a portion of an IC having a RSD according to aspects of the invention;

FIG. 4 depicts a block diagram showing example shapes of a filament region (e.g., a metal oxide insulator) of an RSD according to embodiments of the invention;

FIGS. 5-12 illustrate cross-sectional views depicting the results of fabrication operations in accordance with embodiments of the invention, in which:

FIG. 5 depicts a simplified block diagram showing a cross-sectional view of a portion of a semiconductor wafer after fabrication operations according to aspects of the invention;

FIG. 6 depicts a simplified block diagram showing a cross-sectional view of a portion of a semiconductor wafer after fabrication operations according to aspects of the invention;

FIG. 7 depicts a simplified block diagram showing a cross-sectional view of a portion of a semiconductor wafer after fabrication operations according to aspects of the invention;

FIG. 8 depicts a simplified block diagram showing a cross-sectional view of a portion of a semiconductor wafer after fabrication operations according to aspects of the invention;

FIG. 9 depicts a simplified block diagram showing a cross-sectional view of a portion of a semiconductor wafer after fabrication operations according to aspects of the invention;

FIG. 10 depicts a simplified block diagram showing a cross-sectional view of a portion of a semiconductor wafer after fabrication operations according to aspects of the invention;

FIG. 11 depicts a simplified block diagram showing a cross-sectional view of a portion of a semiconductor wafer after fabrication operations according to aspects of the invention; and

FIG. 12 depicts a simplified block diagram showing a cross-sectional view of a portion of a semiconductor wafer after fabrication operations according to aspects of the invention;

FIG. 13 depicts a simplified block diagram showing a cross-sectional view of a 3D stacked portion of a semiconductor wafer after fabrication operations according to aspects of the invention;

FIGS. 14-19 depict top-down and cross-sectional views showing the results of fabrication operations in accordance with embodiments of the invention, in which:

FIG. 14 depicts a simplified block diagram showing top-down and cross-sectional views of a portion of a semiconductor wafer after fabrication operations according to aspects of the invention;

FIG. 15 depicts a simplified block diagram showing a top-down view of a portion of a semiconductor wafer after fabrication operations according to aspects of the invention;

FIG. 16 depicts a simplified block diagram showing a top-down view of a portion of a semiconductor wafer after fabrication operations according to aspects of the invention;

FIG. 17 depicts a simplified block diagram showing a top-down view of a portion of a semiconductor wafer after fabrication operations according to aspects of the invention;

FIG. 18 depicts a simplified block diagram showing a top-down view of a portion of a semiconductor wafer after fabrication operations according to aspects of the invention; and

FIG. 19 depicts a simplified block diagram showing a top-down view of a portion of a semiconductor wafer after fabrication operations according to aspects of the invention.

### DETAILED DESCRIPTION

It is understood in advance that, although this detailed description provides fabrication methods and resulting structures for a specific RSD architecture, implementing the teachings recited herein are not limited to a particular RSD architecture or operating environment. Rather, embodiments of the present invention are capable of being implemented in conjunction with any other type of RSD (e.g., phase change memory, spin-transfer torque memory, and the like) or operating environment (e.g., RAM, neuromorphic computing applications, etc.), now known or later developed.

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the fabrication of semiconductor devices and semiconductor-based ICs are well known and so, in the interest of brevity, many conventional steps will only be mentioned briefly herein or will be omitted entirely without providing the well-known process details.

Turning now to an overview of technologies that are more specifically relevant to aspects of the present invention, with the growth of digital data applications, there is a need for increasingly fast and scalable memory technologies for data storage and data-driven computation. RRAM is a high speed, high density, and low fabrication-cost NVM technology. Thus, RRAM has the potential to replace and/or complement the limited scaling of flash memories and other silicon-based memories such as dynamic random access memory (DRAM) and static random access memory (SRAM).

A typical RRAM storage cell is a two-terminal device formed as a metal-insulator-metal (MIM) structure/device, which is a simpler construction than the three terminal storage cells used in conventional CMOS-based DRAM or flash memory. MIM structures can also be referred to as RSD structures. The insulator material in the MIM device can be a binary metal oxide, which makes fabricating a MIM RRAM storage cell compatible with silicon-based CMOS fabrication process.

The resistance of a RRAM storage cell serves as the switchable conduction state that stores data. When a sufficient electrical field/signal is applied across the metal electrodes of a MIM/RSD, the resistance of the insulator can be switched from one resistance state to another through various mechanisms, including the formation and rupture of one-dimensional conductive filaments. A process known as electroforming can be used to form one-dimensional conductive filaments in the metal oxide. The formation and rupture of the conducting filaments involves various reduction-oxidation (redox) reactions and depends on the metal/electrode material. A non-limiting example electroforming process can include placing a MIM/RSD in a vacuum and applying a voltage that is in excess of a predetermined critical voltage. Application of the voltage changes properties of the MIM/RSD, including specifically the formation of one-dimensional conductive filaments between the metal electrodes and bridging the insulating gap between the metal electrodes.

The creation of oxygen vacancies in the MIM metal oxide layer is a building block for creating current conducting filaments. Thus, the oxygen vacancy concentration (Vo) in the oxide of the binary metal oxide and the state of the insulator/electrode interface are significant factors in controlling the resistive switching mechanism in a MIM memory cell. Thus, it is desirable to use insulators in the form of oxides with a high mobility of oxygen vacancies, examples of which include, for example, single-layer nonstoichiometric or double-layer oxide structures with ionic bonding. The insulator can be a resistive switching element stack that includes a filament region (e.g., the metal oxide) and a reactive electrode. Oxygen vacancy formation in the filament region can be enhanced by interactions between the metal oxide and the reactive electrode.

Because known electroforming techniques form filaments in random locations of the filament region, the position of conducting filaments formed in the filament region is not under control. The inability to control the position of conducting filaments formed during electroforming results in unwanted device construction variability and performance variability, as well as requiring undesirable higher forming voltages particularly as MIM/RSD elements are scaled to smaller dimensions.

Turning now to an overview of aspects of the invention, embodiments of the invention provide fabrication methods and resulting structures for MIM/RSD storage elements configured and arranged to provide improved control over filament formation in the insulator/filament region (e.g., a metal oxide region) of the MIM/RSD. In embodiments of the invention, the insulator/filament region of the MIM/RSD is provided with a shape that includes an apex region having a peak. In some embodiments of the invention, the apex region is defined by a first filament region sidewall that intersects a second filament region sidewall at the peak such that the first filament region sidewall forms an angle that is less than 90 degrees with respect to the second filament region sidewall. In some embodiments of the invention, the first and second filament region sidewalls are substantially planar. In some embodiments of the invention, the first and second filament region sidewalls are substantially non-planar. An electroforming voltage applied across a filament region that includes an apex region in accordance with aspects of the invention will generate an electric field that is increased or enhanced or concentrated in the apex region, and more specifically at the peak of the apex region. In accordance with aspects of the invention, the level of filament formation in the apex region is greater than the level of filament formation outside the apex region. In accordance with aspects of the invention, the level of filament formation in the apex region is more than half of the total level of filament formation in the filament region. In accordance with aspects of the invention, the level of filament formation at the peak of the apex region is greater than the level of filament formation outside the peak of the apex region. In aspects of the invention, the level of filament formation in the apex region and at the peak of the apex region can be increased by decreasing the angle formed by the intersection of the first filament region sidewall with the second filament region sidewall. In accordance with aspects of the invention, because the electroforming voltage generates an electric field across the filament region that is increased/enhanced/concentrated in the apex region (and/or at the peak of the apex region), filament formation in the filament region is also increased or enhanced or concentrated in the apex region (and/or at the peak of the apex region). Accordingly, embodiments of the invention provide improved control over filament formation in the filament region of the MIM/RSD.

In some aspects of the invention, a MIM/RSD having a filament region with an apex region in accordance with aspects of the invention can be formed by forming a bottom conductive electrode having a predetermined top surface contour. In accordance with aspects of the invention, the predetermined top surface contour is an apex region contour configured and arranged to match the desired contour of the apex region of a to-be-formed filament/insulator region. The filament region is deposited on the bottom conductive electrode, and the apex region contour of the bottom conductive electrode's top surface functions as an apex region template that transfers the apex region contour of the bottom conductive electrode to the filament/insulator region to form therein the apex region having a peak.

In some aspects of the invention, the apex region template of the bottom conductive electrode can be formed by forming a via/opening in an IC and depositing the bottom conductive electrode over and within the via/opening using a sub-atmospheric chemical vapor deposition (SACVD) technique. Known SACVD techniques are conventionally used as part of a multi-stage deposition technique for filling a high aspect-ratio via/opening with a deposited material from the bottom up in a manner designed to ensure that the deposited material does not pinch-off at the top of the via/opening. In a known multi-stage deposition approach, a combination of SACVD and high density plasma-assisted chemical vapor deposition HDP-CVD processes can be employed to fill gaps having high aspect-ratios with a particular material. In the first step of the known multi-stage deposition approach, an initial layer of material is deposited within the via/opening using SACVD. The SACVD deposition technique results in the deposited layer pinching off at the bottom of the via/opening to ensure that no voids are formed in the initial deposited layer. In the second step of the known multi-stage deposition approach, a second layer of the same deposited material is formed over the first layer to fill the volume of the via/opening that remained unfilled after the initial SACVD step. After the via/opening is filled, the deposited material is planarized to prepare the wafer for subsequent processing.

An unintended result of SACVD is that forming the initial layer of material such that it pinches off in the bottom of the via/opening also results in the top surface of the initial layer of material having a contour that matches the above-described apex region contour. However, in known multi-stage deposition techniques, this apex region contour is not put to any use, and is, in effect, lost because it is blended into the second layer of the same material that is deposited using HDP-CVD. In aspects of the invention, an SACVD technique is used in a novel way for the purpose of achieving the above-described apex region contour in the top surface of the bottom conductive electrode. Unlike known SACVD techniques, the apex region contour that results from the SACVD technique is used in accordance with aspects of the invention to create the above-described apex region template on the top surface of the bottom conductive electrode. In a non-limiting example of a suitable SACVD technique, an IC having a via/opening is placed in a semiconductor processing chamber. A reaction is caused to occur in the processing chamber to deposit the bottom conductive electrode layer within the via/opening at a pressure below 1 ATM without applying RF energy to generate a plasma within the processing chamber.

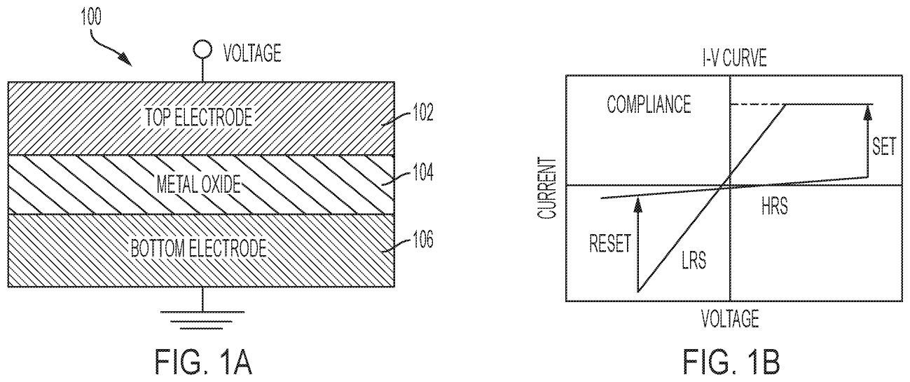

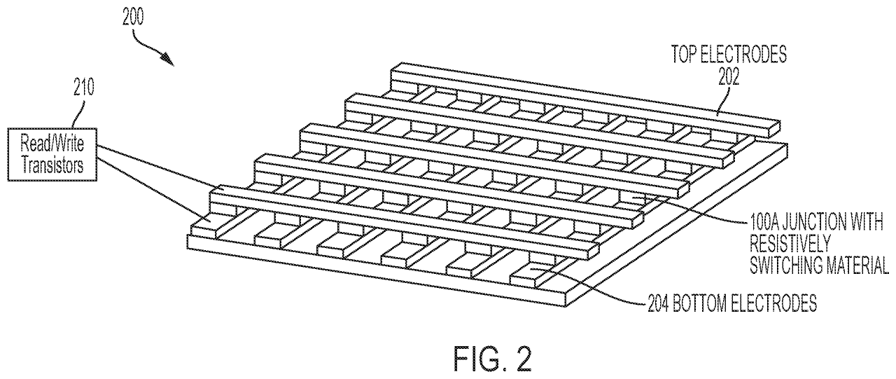

Turning now to a more detailed description of example embodiments of the invention, FIG. 1A depicts a simplified block diagram illustrating a cross-sectional view of a two-terminal RSD component 100, which can be used as a storage cell of an RRAM structure (e.g., crossbar array 200 shown in FIG. 2) capable of incorporating aspects of the invention. The RSD storage cell 100 includes a top electrode 102, a metal oxide active region 104, and a bottom electrode 106, configured and arranged as shown. When a sufficient electrical signal (e.g., a voltage) is applied across the top/bottom electrodes 102, 106, the resistance of the metal oxide 104 can be switched from one resistance state to another. The metal oxide 104 retains its current resistance state until an appropriate electrical signal is applied across the top/bottom electrodes 102, 106 to change it.

FIG. 1B depicts a diagram of an I-V curve illustrating the switching operation of the RSD storage cell 100. The operation principle of the RSD storage cell 100 is based on the reversible resistive switching (RS) between at least two stable resistance states, namely the high resistance state (HRS) and low resistance state (LRS), which occur in the metal oxide 104. In general, the operation that changes the resistance of the storage cell 100 from a high resistance state (HRS) to a low resistance state (LRS) is called a SET process, while the opposite process is defined as a RESET process. The specific resistance state (HRS or LRS) can be retained after the electric stress is cancelled, which indicates the nonvolatile nature of RRAM. For an initial write operation, a voltage larger than the SET voltage is needed in order to “turn on” the resistive switching behaviors of the metal oxide 104 for the subsequent cycles. This is often referred to as the forming process or the electroforming process.

Based on the electrical polarity's relationship between the SET process and the RESET processes, the resistive switching behaviors of the storage cell 100 can be divided into two modes, which are known as a unipolar mode (not shown) and a bipolar mode (shown in FIG. 1B). In the unipolar switching mode, both SET and RESET transitions are achieved by applying electrical voltages of the same polarity (e.g., a positive voltage). In the bipolar switching mode, SET and RESET transitions are executed by applying voltages of opposite polarities (e.g., a positive voltage SET and a negative voltage RESET). In both cases, the current is limited by a compliance level during the abrupt set transition in order to suitably control the size of current conducting filament and the corresponding LRS resistance value.

Because RSD storage cell 100 uses only two external terminals, these memories can be accommodated in a crossbar array 200, which is shown in FIG. 2. The crossbar array 200 illustrates how the RSD storage cell 100 shown in FIG. 1A can be utilized as an addressable cross-point memory/storage cell 100A of the crossbar array 200, which is capable of incorporating aspects of the invention. The array 200 includes perpendicular conductive top electrode lines 202 (e.g., wordline rows), conductive bottom electrode lines 204 (e.g., bitline columns), and resistive switching element memory/storage cells 100A at the intersection between each top electrode line 202 and bottom electrode line 204. Contact liners/metals (not shown) can be used to couple the resistive switching element memory/storage cell 100A to the top and bottom electrode lines 202, 204. The storage cell 100A and electrode lines 202, 204 can be configured to operate the same as the storage cell 100 shown in FIG. 1A. Each storage cell 100A can be accessed for read and write by using transistors 210 to bias the corresponding top electrode line 202 and bottom electrode line 204. The transistors 210 are communicatively coupled in a known manner to each of the top electrode lines 202 and the bottom electrode lines 204.

The crossbar array 200 is compatible with a variety of electronic circuits and devices, including ultra-high density NVM and artificial neural network (ANN) architectures. In neuromorphic computing applications (e.g., ANN), the RSD 100, 100A can be used as a connection (synapse) between a pre-neuron and a post-neuron, thus representing the connection weight in the form of device resistance. Neuromorphic systems are interconnected processor elements that act as simulated “neurons” and exchange “messages” between each other in the form of electronic signals. Similar to the so-called “plasticity” of synaptic neurotransmitter connections that carry messages between biological neurons, the connections in neuromorphic systems such as ANNs carry electronic messages between simulated neurons, which are provided with numeric weights that correspond to the strength or weakness of a given connection. The weights can be adjusted and tuned based on experience, making neuromorphic systems adaptive to inputs and capable of learning. For example, a neuromorphic/ANN for handwriting recognition is defined by a set of input neurons, which can be activated by the pixels of an input image. After being weighted and transformed by a function determined by the network's designer, the activations of these input neurons are then passed to other downstream neurons, which are often referred to as “hidden” neurons. This process is repeated until an output neuron is activated. The activated output neuron determines which character was read. Multiple pre-neurons and post-neurons can be connected through an array of RRAMs, which naturally expresses a fully-connected neural network.

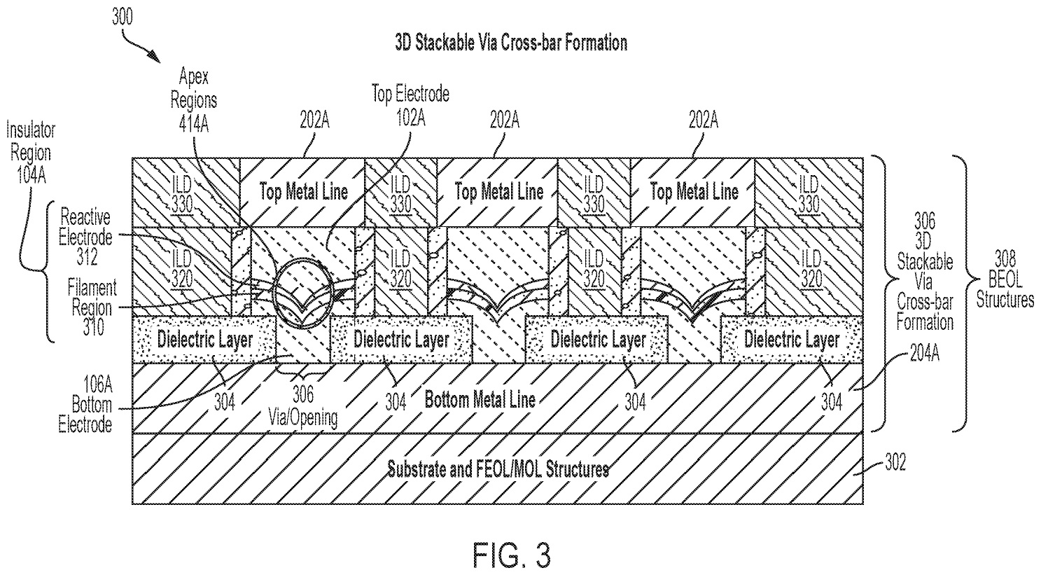

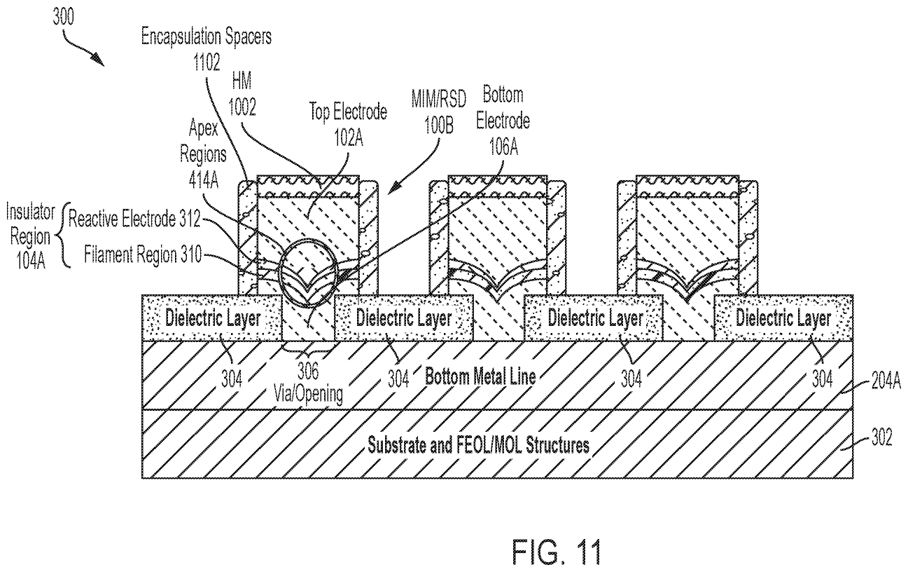

FIG. 3 depicts a portion of an IC 300 having formed therein a MIM/RSD 100B (best shown in FIG. 11) in accordance with aspects of the invention. In FIG. 3, the MIM/RSD includes but is not limited to a bottom electrode 106A, an insulator region 104A, and a top electrode 102A, configured and arranged as shown. The MIM/RSD 100B is configured and arranged as part of a three-dimensional (3D) stackable via cross-bar formation 306 of the IC 300. In general, the 3D stackable via cross-bar formation 306 is among the BEOL (back-end-of-line) structures 308 of the IC 300. The 3D stackable via cross-bar formation 306 includes, but is not limited to, a bottom metal line 204A, the MIM/RSD 100B, and a top metal line 202A, configured and arranged as shown. The 3D stackable via cross-bar formation 306 corresponds in general to the cross-bar array 200 (shown in FIG. 2); the bottom metal line 204A corresponds in general to the bottom electrode line 204 (shown in FIG. 2); the MIM/RSD 100B corresponds in general to the addressable cross-point memory/storage cell 100A (shown in FIG. 2); and the top metal line 202A corresponds in general to the top electrode line 202 (shown in FIG. 2). The 3D stackable via cross-bar formation 306 is formed over a substrate and FEOL/MOL (front-end-of-line/middle-of-line) structure 302, as well as within a dielectric layer 304 and interlayer dielectric (ILD) regions 320, 330.

The substrate and FEOL/MOL structures 302 represent a variety of IC structures to which the 3D stackable via cross-bar formation 306 can be communicatively coupled. In general, ICs are fabricated in a series of stages, including a FEOL stage, a MOL stage and a BEOL stage. The process flows for fabricating modern ICs are often identified based on whether the process flows fall in the FEOL stage, the MOL stage, or the BEOL stage. Generally, the FEOL stage is where device elements (e.g., transistors, capacitors, resistors, etc.) are patterned in the semiconductor substrate/wafer. The FEOL stage processes include wafer preparation, isolation, gate patterning, and the formation of wells, source/drain (S/D) regions, extension junctions, silicide regions, and liners. The MOL stage typically includes process flows for forming the contacts (e.g., CA) and other structures that communicatively couple to active regions (e.g., gate, source, and drain) of the device element. For example, the silicidation of source/drain regions, as well as the deposition of metal contacts, can occur during the MOL stage to connect the elements patterned during the FEOL stage. Layers of interconnections are formed above these logical and functional layers during the BEOL stage to complete the IC. Most ICs need more than one layer of wires to form all the necessary connections, and as many as 5-12 layers are added in the BEOL process. The various BEOL layers are interconnected by vias that couple from one layer to another.

As previously noted, the MIM/RSD 100B includes but is not limited to the bottom electrode 106A, the insulator region 104A, and the top electrode 102A, configured and arranged as shown. The insulator region 104A includes a filament region 310 and a reactive electrode region 312. In some embodiments of the invention, the reactive electrode region 312 is not included in the insulator region 104A. Encapsulation spacers 1102 are provided on sidewalls of the MIM/RSD 100B to protect the filaments and oxygen vacancies in the filament regions 310 from oxygen penetration that can result from subsequent IC fabrication processes.

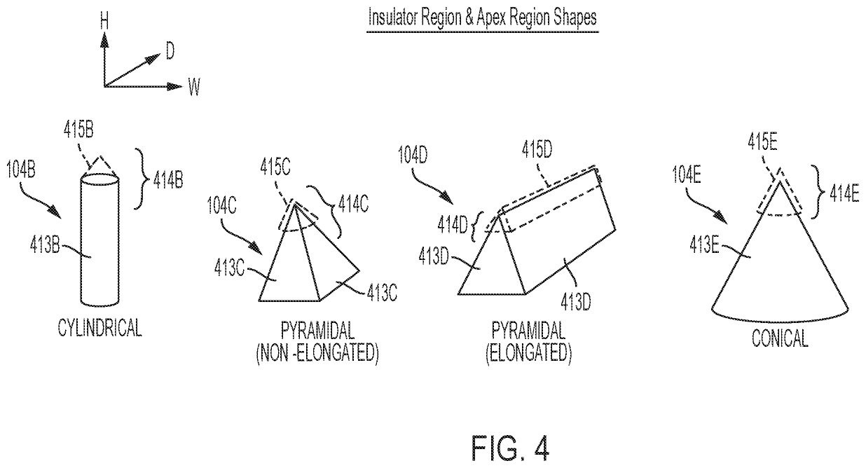

In accordance with aspects of the invention, the filament region 310 includes an apex region 414A having a peak (e.g., peaks 415B, 415C, 415D, 415C shown in FIG. 4) configured and arranged to provide improved control over filament formation in the filament region 310. In some aspects of the invention, the apex region 414A and its peak can point downward as depicted in FIG. 3. In some embodiments of the invention, the apex region 414A and its peak can point upward or laterally. In embodiments of the invention, the apex region 414A is defined by a first filament region sidewall that intersects a second filament region sidewall at the peak such that the first filament region sidewall forms an angle that is less than 90 degrees with respect to the second filament region sidewall. Additional examples of suitable apex regions 414B, 414C, 414D, 414E are shown in FIG. 4. An electroforming voltage (e.g., a write operation) applied across the filament region 310, which includes any of the apex regions 414A, 414B, 414C, 414D, 414E, will generate an electric field that is increased or enhanced or concentrated in the apex region 414A, 414B, 414C, 414D, 414E. In accordance with aspects of the invention, because the electric field is increased/enhanced/concentrated in the apex region 414A, 414B, 414C, 414D, 414E, filament formation is also increased or enhanced or concentrated in the apex region 414A, 414B, 414C, 414D, 414E. Accordingly, the apex region 414A, 414B, 414C, 414D, 414E, in accordance with embodiments of the invention, provides improved control over filament formation in the filament region 310.

In some aspects of the invention, the apex region 414A can be formed by forming the bottom electrode 160A to include a top surface having a predetermined top surface contour. In accordance with aspects of the invention, the predetermined top surface contour matches the desired contour of the apex region 414A (or 414B, 414C, 414D, 414E shown in FIG. 4) of the filament region 310. The filament region 310 is deposited on the bottom electrode 106A, and the predetermined top surface contour of the bottom electrode 106A functions as a template that such that the predetermined top surface contour of the bottom electrode 106A is transferred to the filament region 310 to form therein the apex region 414A having a peak (e.g., peaks 415B, 415C, 415D, 415C shown in FIG. 4).

In some aspects of the invention, the bottom electrode 106A and its predetermined top surface contour can be formed by forming a via/opening 306 in the dielectric layer 304 and using a SACVD technique to deposit the bottom electrode 106A over and within the via/opening 306. In some aspects of the invention, the via/opening 306 can have a high aspect-ratio (i.e., the via/opening is taller than it is wide). In some aspects of the invention, the via/opening 306 does not have a high aspect-ratio (i.e., the via/opening is not taller than it is wide). In aspects of the invention, the SACVD technique is used in a novel way to achieve the predetermined top surface contour of the bottom electrode 106A that matches the desired contour of the apex region 414A. In a non-limiting example of a suitable SACVD technique, an IC having a via/opening is placed in a semiconductor processing chamber. A reaction is caused to occur in the processing chamber to deposit the bottom electrode layer 106A within the via/opening 306 at a pressure below 1 ATM without applying RF energy to generate a plasma within the processing chamber.

FIG. 4 depicts a block diagram showing additional example shapes of filament regions 104B, 104C, 104D, 104E having apex regions 414B, 414C, 414D, 414E that terminate at peaks 415B, 415C, 415D, 415E. Known semiconductor fabrication techniques can be used to fabrication the filament regions 104B, 104C, 104D, 104E and incorporate them into the MIM/RSD 100B (best shown in FIG. 11). A variety of known fabrication operations (e.g., ion beam etching (IBE)) are suitable for forming the filament regions 104B, 104C, 104D, 104E and incorporating them into the MIM/RSD 100B so the details of such operations have been omitted in the interest of brevity. The orientation of the filament regions 104B, 104C, 104D, 104E, the apex regions 414B, 414C, 414D, 414E, and the peaks 415B, 415C, 415D, 415E shown in FIG. 4 are for ease of illustration and explanation. In some embodiments of the invention, the orientation of the filament regions 104B, 104C, 104D, 104E, the apex regions 414B, 414C, 414D, 414E, and the peaks 415B, 415C, 415D, 415E can be pointed downward or laterally. As shown in FIG. 4, filament region 104B depicts an example of a cylindrical filament region 104B, filament region 104C depicts an example of a non-elongated pyramidal shape, filament region 104D depicts an example of a non-elongated pyramidal shape, and filament region 104E depicts an example of a conical shape. Each filament region 104B, 104C, 104D, 104E defines exterior surfaces 413B, 413C, 413D, 413E and apex regions 414B, 414C, 414D, 414E. In some embodiments of the invention, the apex regions 414B, 414C, 414D, 414E are configured to terminate at peaks 415B, 415C, 415D, 415E.

As shown in FIG. 4, each filament region 104B, 104C, 104D, 104E includes a height (H) dimension, a width (W) dimension and a depth (D) dimension. The W, D and H dimensions of the filament regions 104B, 104C, 104D, 104E can vary according to design considerations. For example, the W, D and H dimensions of the filament regions 104B, 104C, 104D, 104E can be designed to have predetermined values, to have values within predetermined ranges, to have values having fixed ratios with respect to each other, or to have values based on any other consideration or combination of considerations in accordance with the functionality of filament region 104B, 104C, 104D, 104E described herein. More specifically, the W, D and H dimensions of the filament regions 104B, 104C, 104D, 104E can be designed to have predetermined values

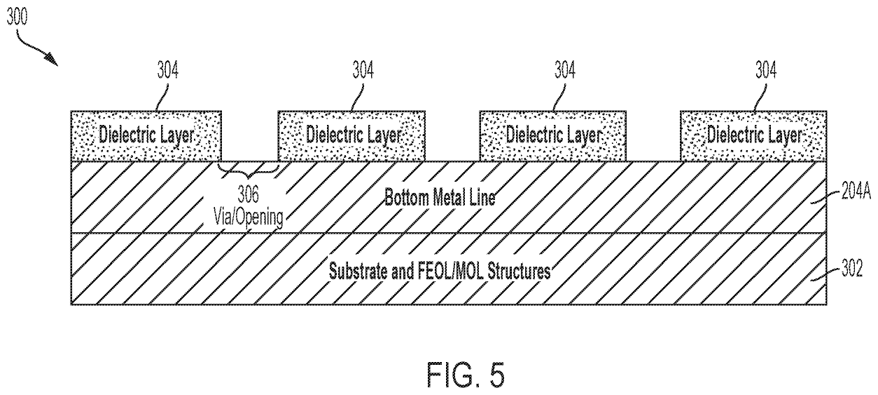

FIGS. 5-12 depict the results of various fabrication operations that illustrate a method for forming the IC 300 shown in FIG. 3 in accordance with aspects of the invention. FIG. 5 depicts a cross-sectional view of a portion of the IC 300 after an initial set of fabrication having been used to form the structures shown. At this stage of the fabrication process, the IC 300 includes the substrate and FEOL/MOL structures 302, the bottom metal line 204A, the dielectric layer 304, and the vias/openings 306, configured and arranged as shown. A variety of known fabrication operations are suitable for forming the substrate and FEOL/MOL structures 302 and the bottom metal line 204A so the details of such operations have been omitted in the interest of brevity. The dielectric layer 304 and vias/openings 306 can be formed by depositing the dielectric layer 304 on the bottom metal line 204A then patterning and etching the dielectric layer 304 to form the vias/openings 306. In some aspects of the invention, the dielectric layer 304 can be a low-k dielectric. In general, a low-k dielectric is a material having a dielectric constant that is less than silicon dioxide (SiO₂). Suitable low-k dielectric material includes but is not limited to fluorine-doped SiO₂, porous organosilicate glass material (e.g., SiCOH), porous SiO₂, and organic polymeric materials such as polyimide, polynorbornenes, benzocyclobutene, and hydrogen sisesquioxane.

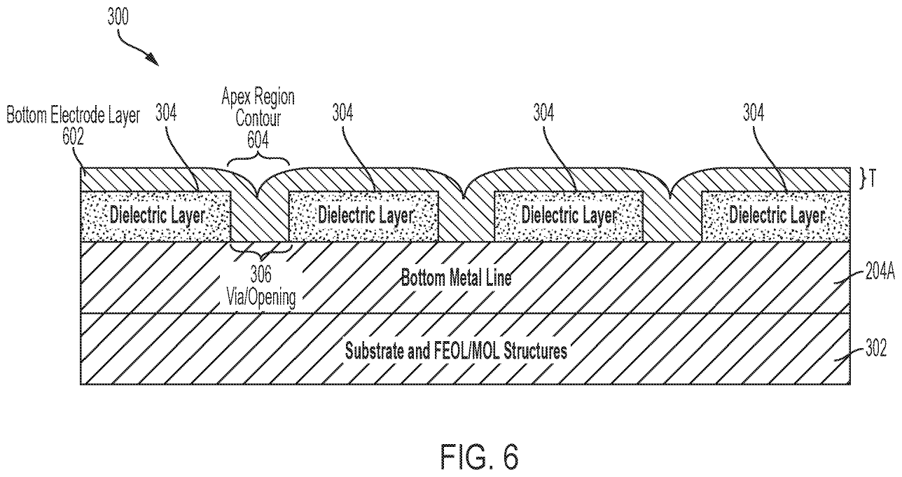

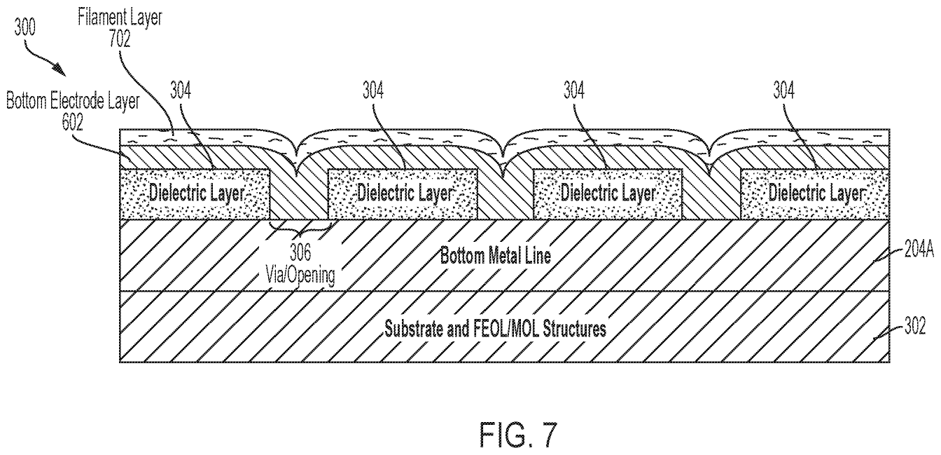

In FIG. 6, a bottom electrode layer 602 has been deposited over the dielectric layer 304 and the vias/openings 306. In accordance with aspects of the invention, the bottom electrode layer 602 is configured and arranged to include a predetermined top surface contour. In accordance with aspects of the invention, the portion of the predetermined top surface contour that is over the via/opening 306 is an apex region contour 604 configured and arranged to function as an apex region template that matches the desired contour of the apex region 415A (shown in FIG. 3) of a to-be-formed filament/insulator layer 702 (shown in FIG. 7). In some embodiments of the invention, the bottom electrode layer 602 can include an optional metal barrier layer (e.g., an ALD of TaN) (not shown). The optional barrier layer can protect against metal diffusion for certain type of bottom electrode metal materials (e.g., Cu) but is not needed for other types of bottom electrode metal (e.g., W). The bottom electrode layer 602 can be any suitable conductive material, including but not limited to TiN, TaN, Cu, W, or any other suitable metal.

In some aspects of the invention, the apex region contour/template 604 can be formed by using a SACVD process to deposit the bottom electrode layer 602 over the dielectric layer 304 and the via/opening 306. In a non-limiting example of a suitable SACVD technique, the IC 300 can be placed in a semiconductor processing chamber (not shown). A reaction is caused to occur in the processing chamber to deposit the bottom electrode layer 602 over the dielectric layer 304 and within the via/opening 306 at a pressure below about 1 ATM without applying RF energy to generate a plasma within the processing chamber.

In aspects of the invention, the size and shape (including the depth) of the apex region contour/template 604 can be tuned by controlling a number of parameters, including but not limited to the thickness T of the bottom electrode layer 602, as well as the aspect-ratio of the via/opening 306. In some embodiments of the invention, the thickness T of the bottom electrode layer 602 can be from about 15 nm to about 40 nm.

In FIG. 7, known deposition processes (e.g., ALD) have been used to conformally deposit a filament region layer 702 over the bottom electrode 602 such that the apex contour/template 604 (shown in FIG. 6) is transferred to the portion of the filament region layer 702 that is over the via/opening 306, thereby forming the apex region 415A. In aspects of the invention, the filament region layer 702 can be formed from a metal oxide (e.g., HfOₓ, TaOₓ, TiOₓ).

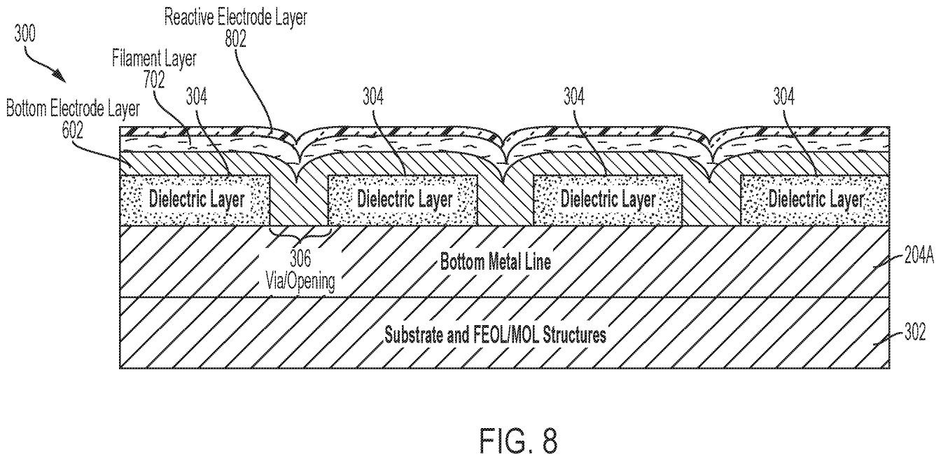

In FIG. 8, known fabrication operations have been used to deposit a reactive electrode layer 802 (e.g. an ALD of TiN/Al-containing alloy/TiN, or a PVD of Ti, Al, TiN, and laminates/alloys thereof) over the filament region layer 702 such that the apex region 415A (shown in FIG. 7) is transferred to the portion of the reactive electrode layer 802 that is over the via/opening 306. In embodiments of the invention, the reactive electrode layer 802 can include an optional barrier layer (e.g., an ALD of TaN) (not shown).

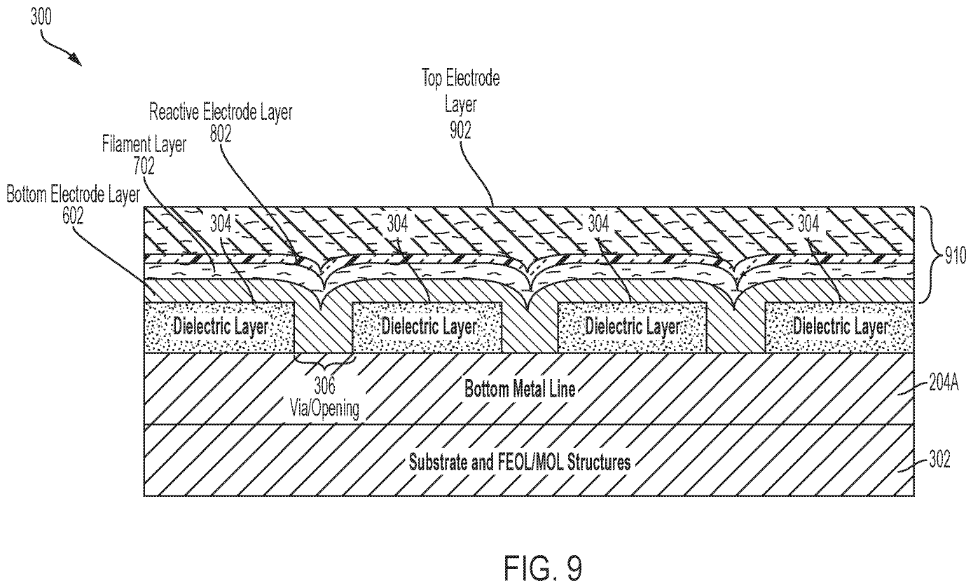

In FIG. 9, known fabrication operations (e.g., CVD or ALD) have been used to deposit and CMP a top electrode layer 902 over the reactive electrode layer 802. In embodiments of the invention, the top electrode layer 902 can be any suitable conductive metal, including but not limited to TaN. After the fabrication operations shown in FIG. 9, a complete resistive switching element stack 910 has been formed in accordance with aspects of the invention.

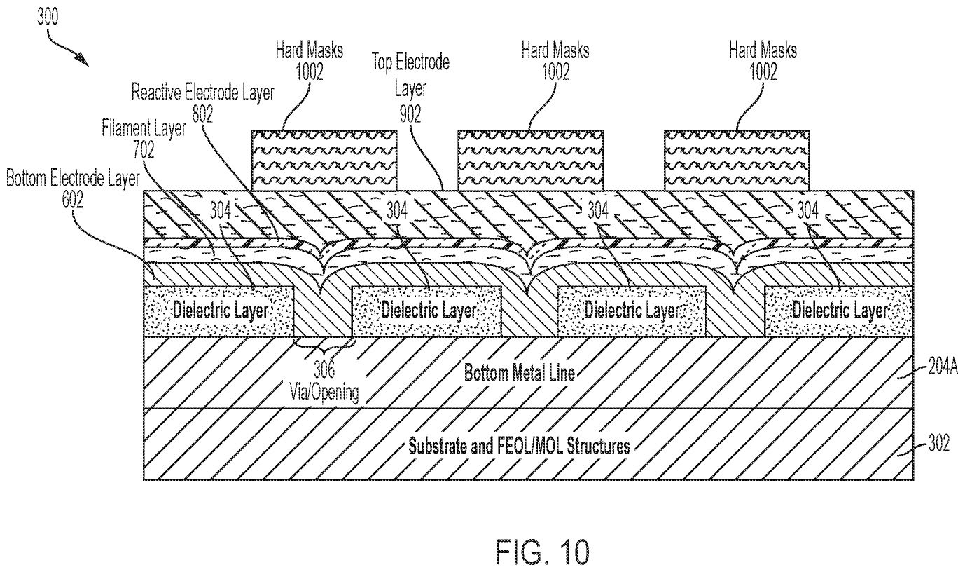

In FIG. 10, known fabrication operations have been used to deposit a hard mask layer (not shown), pattern the hard mask layer, and etch the hard mask layer to form hard masks 1002.

In FIG. 11, the portions of the resistive switching element 910 (shown in FIG. 9) that are not under the hard masks 1002 have been etched (e.g., using a RIE) to form the MIM/RSD 100B having a bottom electrode 106A, an insulator region 104A, and a top electrode 102A. In aspects of the invention, the insulator region 104A can include a filament region 310 and a reactive electrode 312. Additionally, known fabrication operations have been used form encapsulation spacers 1102 (e.g., SiN) on sidewalls of the MIM/RSD 100B. The encapsulation spacers 1102 protect the filaments and oxygen vacancies in the filament region 310 from oxygen penetration that can result from subsequent IC fabrication processes.

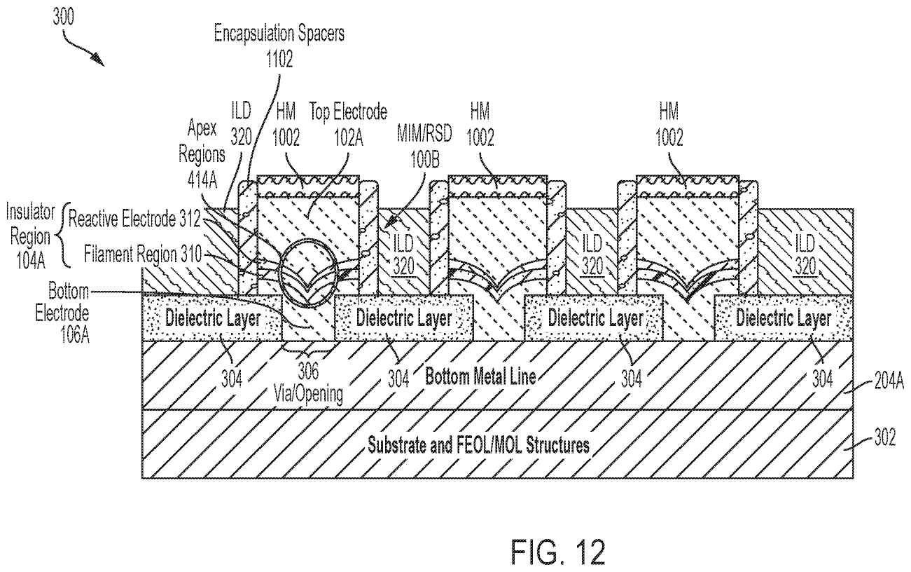

In FIG. 12, an interlayer dielectric (ILD) region 320 formed over the IC 300 and planarized (e.g., using CMP). In embodiments of the invention, the ILD region 320 can be SiO₂ or any suitable low-k material.

After the fabrication operations depicted in FIG. 12, known fabrication operations are used to form the IC structure 300 shown in FIG. 3. As best shown in FIGS. 3 and 11, the ILD 330 and the top metal lines 202A have been formed over the ILD 320 and the MIM/RSD 100B. The ILD 330 and the top metal lines 202A can be formed by depositing the ILD layer 330 on the IC structure 300 shown in FIG. 12 then patterning and etching the ILD 330 to form vias/openings in which the top metal lines 202A will be formed. The hard masks 1102 (shown in FIG. 12) are removed by the etch applied to the ILD 330. In embodiments of the invention, the ILD 330 can be SiO₂ or any suitable low-k material. Known fabrication operations (e.g. sputtering, etc.) can be used to deposit the top metal lines 202A in the vias/openings formed in the ILD 330, and a CMP process can be applied to planarize the IC structure 300.

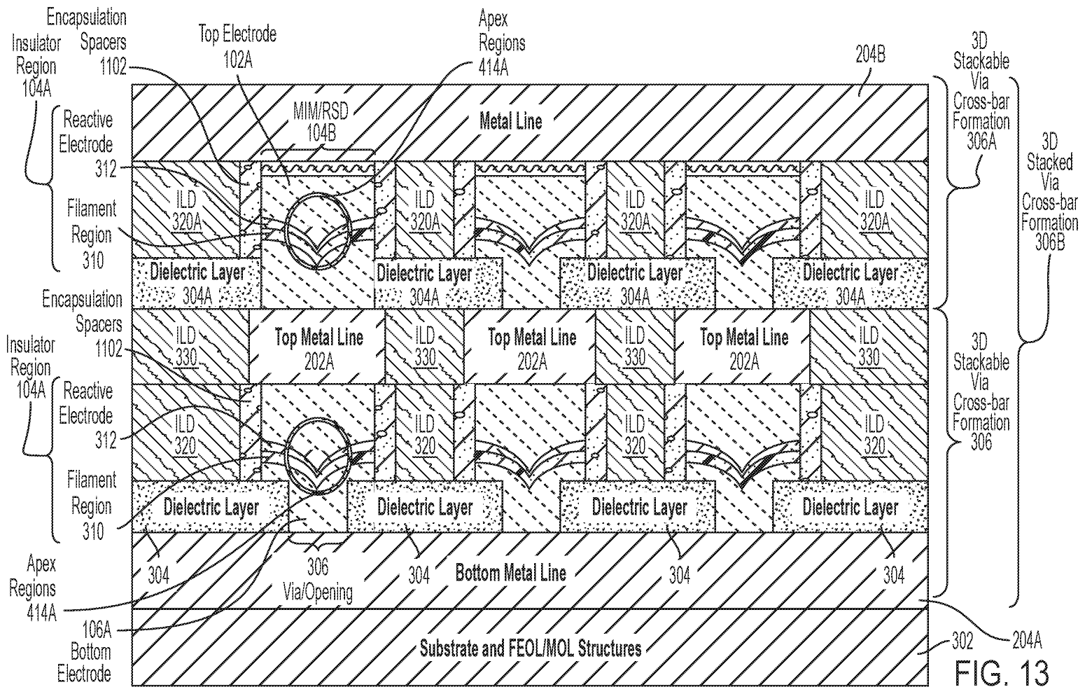

FIG. 13 depicts a version of the IC structure 300 that includes a 3D stacked via cross-bar formation 306B formed from a 3D stackable via cross-bar formation 306A formed on the 3D stackable via cross-bar formation 306. The 3D stackable via cross-bar formation 306A includes, but is not limited to, a dielectric layer 304A, an ILD 320A, a MIM/RSD 100B (best shown in FIG. 11), and a metal line 204A, configured and arranged as shown. The 3D stackable via cross-bar formation 306A corresponds in general to the cross-bar array 200 (shown in FIG. 2); the MIM/RSD 100B corresponds in general to the addressable cross-point memory/storage cell 100A (shown in FIG. 2); and the metal line 204B corresponds in general to the bottom electrode line 204 (shown in FIG. 2). The 3D stackable via cross-bar formation 306A is formed over a substrate and FEOL/MOL (front-end-of-line/middle-of-line) structure 302, as well as within a dielectric layer 304 and interlayer dielectric (ILD) regions 320, 330. The 3D stackable via cross-bar formation 306A can be fabricated using substantially the same fabrication operations used to form the bottom metal line 204A, the dielectric layer 304, the ILD 320, and the MIM/RSD 100B of the 3D stackable via cross-bar formation 306, except that in the 3D stackable via cross-bar formation 306A the hard mask 104B is not removed by an ILD etch operation.

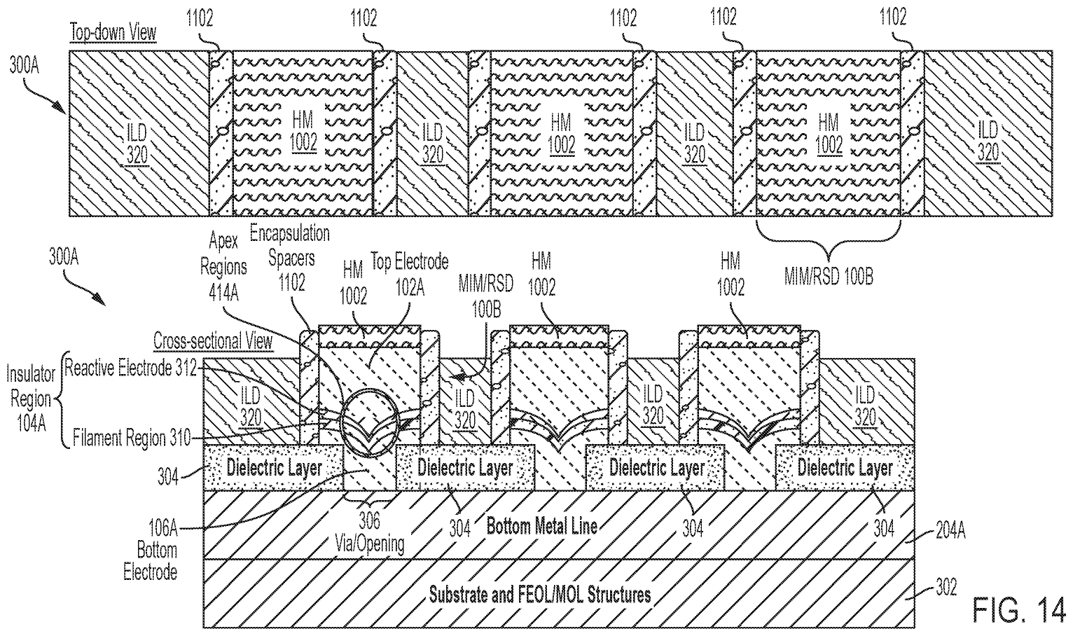

FIGS. 14-19 depict top-down and cross-sectional views of portions of an IC 300A showing the results of fabrication operations in accordance with embodiments of the invention. More specifically, FIG. 14 depicts a simplified block diagram showing top-down and cross-sectional views of the IC 300A after fabrication operations according to aspects of the invention. At this fabrication stage, substantially the same fabrication operations that were used to form the IC 300 to the fabrication stage shown in FIG. 12 have been used to form the IC 300A to the fabrication stage shown in FIG. 14.

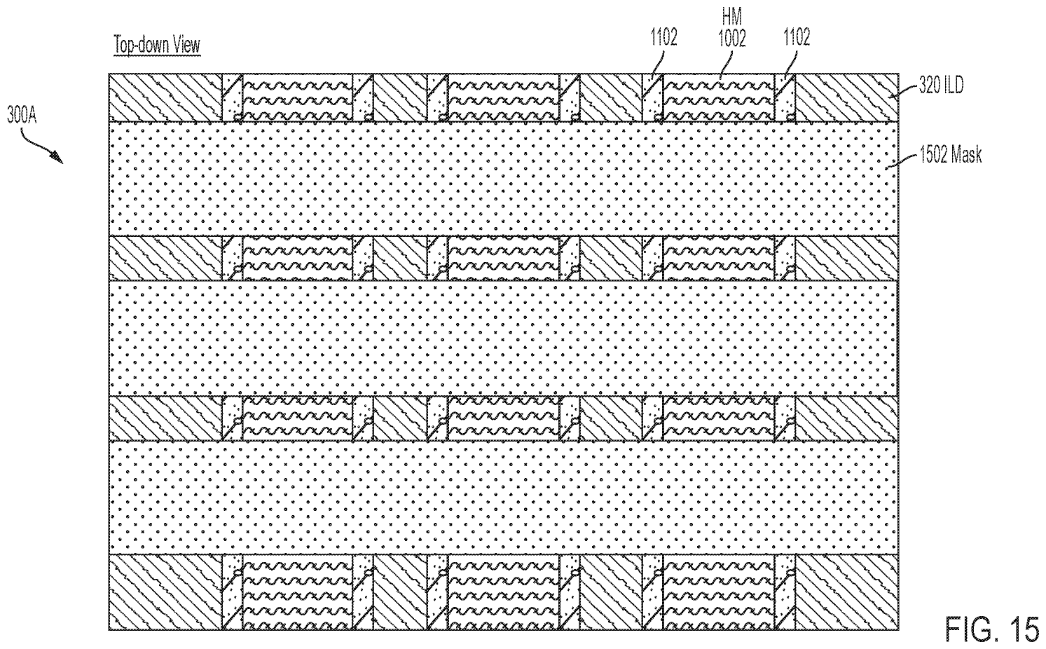

FIG. 15 depicts a simplified block diagram showing a top-down view of the IC 300A after known fabrication operations have been used to deposit masks 1502 over selected portions of the IC 300A. An example fabrication operation for forming the masks 1502 can include depositing a layer of mask material (not shown) over the IC 300A then patterning and etching the mask layer to form the masks 1502. In some embodiments of the invention, the masks 1502 can be an organic planarization layer (OPL). In general, OPLs are used as etch masks for pattern transfers into inorganic substrates, to fill pre-existing features, and to planarize the substrate to allow for larger patterning process windows.

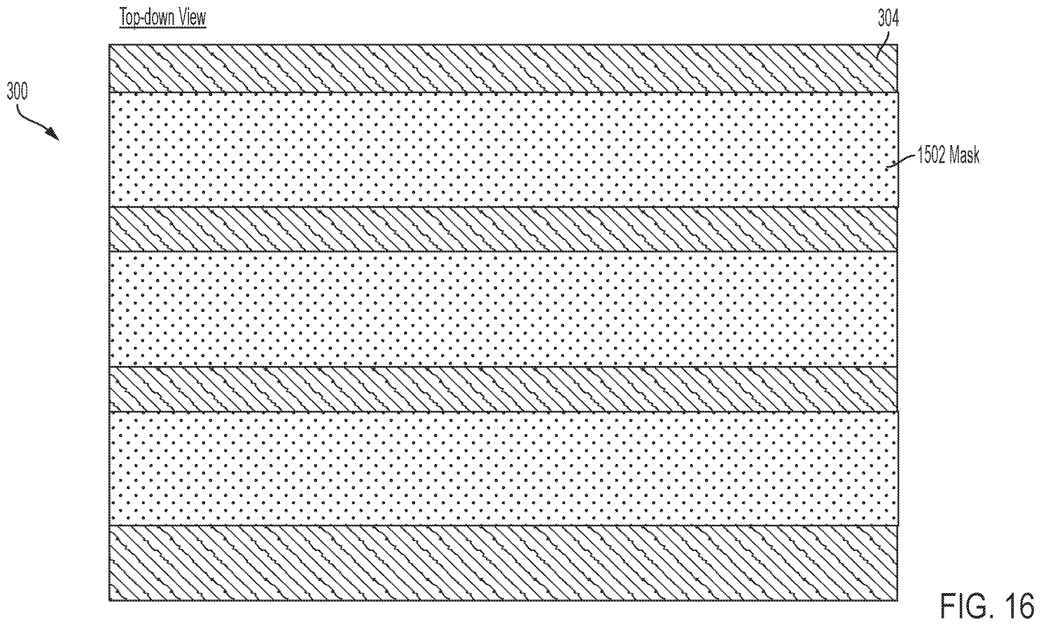

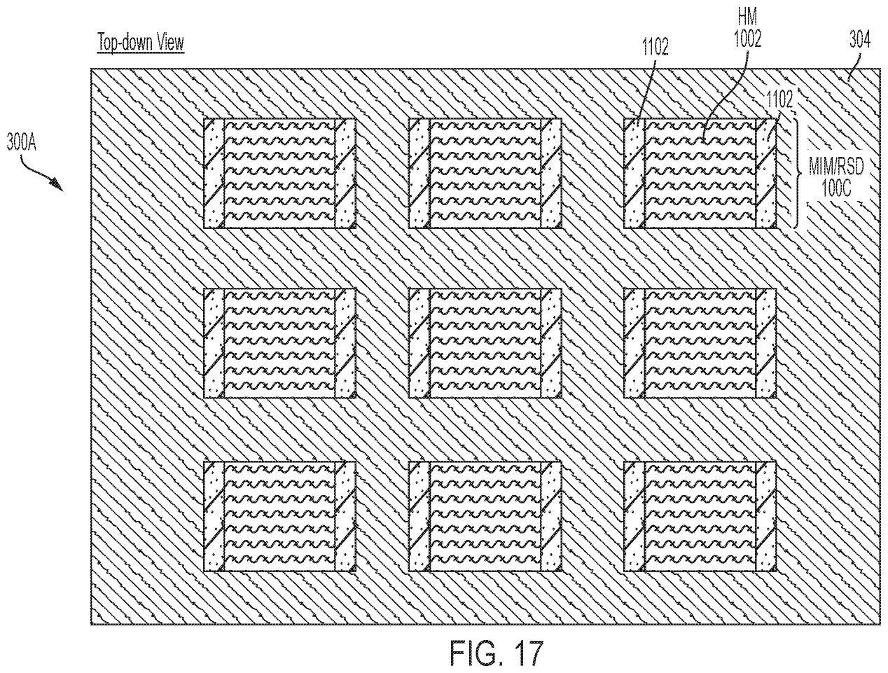

In FIG. 16, known fabrication operations have been used to etch the portions of the IC 300A that are not covered by the masks 1502, thereby forming MIM/RSD elements 100C (shown in FIG. 17). In some embodiments of the invention, the MIM/RSD elements 100C can be substantially square-shaped in the top-down view. In some embodiments of the invention, the MIM/RSD elements 100C can be non-square-shaped (e.g., rectangular) in the top-down view.

In FIG. 17, known fabrication operations have been used to remove the masks 1502 to show the MIM/RSD elements 100C.

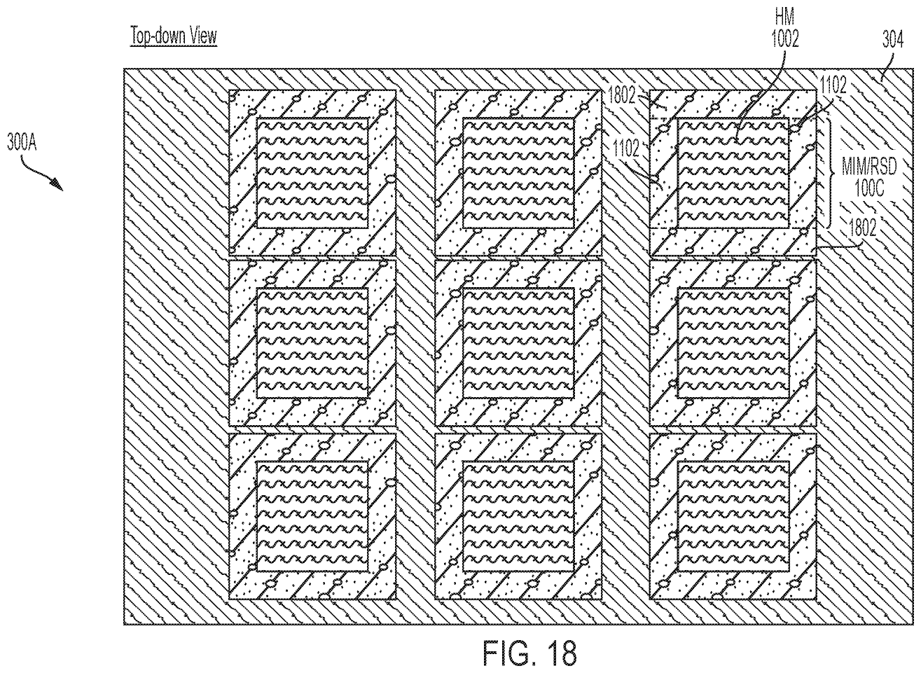

In FIG. 18, known fabrication operations have been used to form additional encapsulation spacers 1802 on exposed sidewalls of the MIM/RSD elements 100C. The encapsulation spacers 1802 (e.g., SiN) protect the filaments and oxygen vacancies in the filament region of the MIM/RSD elements 100C from oxygen penetration that can result from subsequent IC fabrication processes.

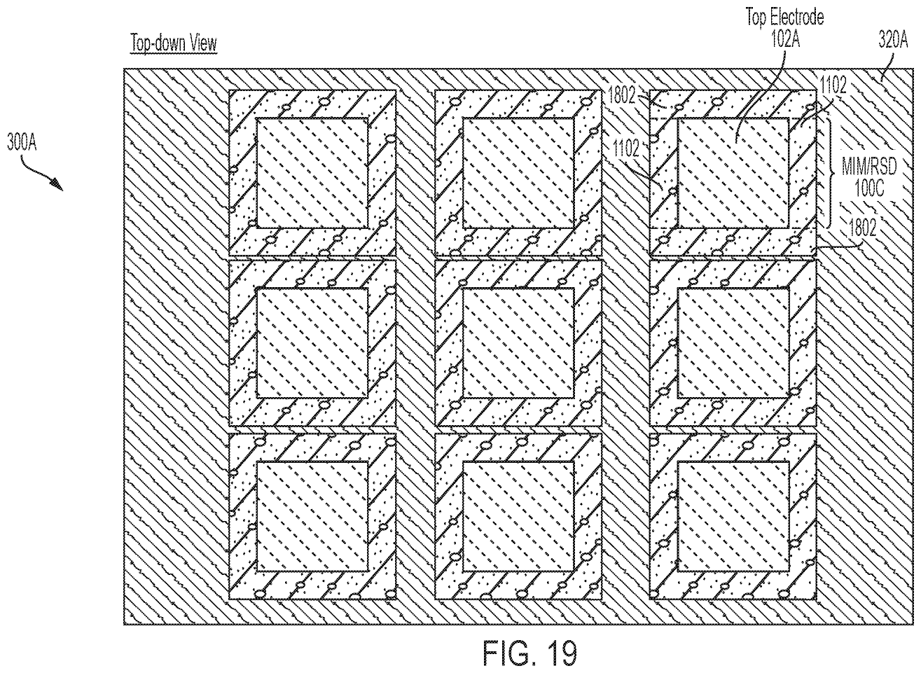

FIG. 19 additional ILD regions 320A have been deposited and planarized (e.g., using CMP) down through the hard masks 1102 (shown in FIG. 18), thereby removing the hard masks 1102 and exposing a top electrode 102A of each MIM/RSD 100C. After the fabrication operations depicted in FIG. 19, the fabrication operations depicted in FIGS. 3 and 13 can be applied to the IC structure 300C with appropriate modifications for forming the shape of the MIM/RSD 100C.

In embodiments of the invention, low resistivity metals can be used to form the various metal components of the 3D stacked via cross-bar formations 306B, including but not limited to the bottom electrodes 106A and the top electrodes 102A. In embodiment of the invention, the resistivity values (“ρ”) for the low resistivity metals can be between about 1×10⁻⁸ ohm meters and about 3×10⁻⁶ ohm meters. A material can generally be considered to have low resistivity if its resistivity is below about 1×10⁶ ohm meters. The electrical resistivity of a particular conductor material is a measure of how strongly the material opposes the flow of electric current through it. This resistivity factor, sometimes called its “specific electrical resistance,” enables the resistance of different types of conductors to be compared to one another at a specified temperature according to their physical properties without regards to their lengths or cross-sectional areas. Thus, the higher the resistivity value of p the more resistance and vice versa. For example, the resistivity of a good conductor such as copper is on the order of 1.72×10⁻⁸ ohm meters, whereas the resistivity of a poor conductor (insulator) such as air can be well over 1.5×10¹⁴ ohm meters. Materials such as Cu and Al are known for their low levels of resistivity thus allowing electrical current to easily flow through them making these materials.

The methods described herein are used in the fabrication of IC chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

Various embodiments of the present invention are described herein with reference to the related drawings. Alternative embodiments can be devised without departing from the scope of this invention. Although various connections and positional relationships (e.g., over, below, adjacent, etc.) are set forth between elements in the following description and in the drawings, persons skilled in the art will recognize that many of the positional relationships described herein are orientation-independent when the described functionality is maintained even though the orientation is changed. These connections and/or positional relationships, unless specified otherwise, can be direct or indirect, and the present invention is not intended to be limiting in this respect. Similarly, the term “coupled” and variations thereof describes having a communications path between two elements and does not imply a direct connection between the elements with no intervening elements/connections between them. All of these variations are considered a part of the specification. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” are understood to include any integer number greater than or equal to one, i.e. one, two, three, four, etc. The terms “a plurality” are understood to include any integer number greater than or equal to two, i.e. two, three, four, five, etc. The term “connection” can include an indirect “connection” and a direct “connection.”

References in the specification to “one embodiment,” “an embodiment,” “an example embodiment,” etc., indicate that the embodiment described can include a particular feature, structure, or characteristic, but every embodiment may or may not include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper,” “lower,” “right,” “left,” “vertical,” “horizontal,” “top,” “bottom,” and derivatives thereof shall relate to the described structures and methods, as oriented in the drawing figures. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements.

Spatially relative terms, e.g., “beneath,” “below,” “lower,” “above,” “upper,” and the like, can be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device can be otherwise oriented (rotated 90 degrees or at other orientations) and the spatially relative descriptors used herein interpreted accordingly.

The terms “about,” “substantially,” “approximately,” and variations thereof, are intended to include the degree of error associated with measurement of the particular quantity based upon the equipment available at the time of filing the application. For example, “about” can include a range of ±8% or 5%, or 2% of a given value.

The phrase “selective to,” such as, for example, “a first element selective to a second element,” means that the first element can be etched and the second element can act as an etch stop.

The term “conformal” (e.g., a conformal layer) means that the thickness of the layer is substantially the same on all surfaces, or that the thickness variation is less than 15% of the nominal thickness of the layer.

As previously noted herein, for the sake of brevity, conventional techniques related to semiconductor device and integrated circuit (IC) fabrication may or may not be described in detail herein. By way of background, however, a more general description of the semiconductor device fabrication processes that can be utilized in implementing one or more embodiments of the present invention will now be provided. Although specific fabrication operations used in implementing one or more embodiments of the present invention can be individually known, the described combination of operations and/or resulting structures of the present invention are unique. Thus, the unique combination of the operations described in connection with the fabrication of a semiconductor device according to the present invention utilize a variety of individually known physical and chemical processes performed on a semiconductor (e.g., silicon) substrate, some of which are described in the immediately following paragraphs.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), chemical-mechanical planarization (CMP), and the like. Reactive ion etching (RIE), for example, is a type of dry etching that uses chemically reactive plasma to remove a material, such as a masked pattern of semiconductor material, by exposing the material to a bombardment of ions that dislodge portions of the material from the exposed surface. The plasma is typically generated under low pressure (vacuum) by an electromagnetic field. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photo-resist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

The flowchart and block diagrams in the Figures illustrate possible implementations of fabrication and/or operation methods according to various embodiments of the present invention. Various functions/operations of the method are represented in the flow diagram by blocks. In some alternative implementations, the functions noted in the blocks can occur out of the order noted in the Figures. For example, two blocks shown in succession can, in fact, be executed substantially concurrently, or the blocks can sometimes be executed in the reverse order, depending upon the functionality involved.

The descriptions of the various embodiments of the present invention have been presented for purposes of illustration, but are not intended to be exhaustive or limited to the embodiments described. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

What is claimed is:

1. An integrated circuit structure comprising:
a resistive switching device (RSD) comprising:
a bottom conductive electrode;
an insulator region communicatively coupled to the bottom conductive electrode, wherein the insulator region comprises a filament region; and
a top conductive electrode communicatively coupled to the insulator region;
wherein the filament region comprises an apex region comprising a first apex region sidewall and a second apex region sidewall; and
wherein the second apex region sidewall intersects the first apex region sidewall at an angle that is less than about 90 degrees.

2. The structure of claim 1, wherein the first apex region sidewall is substantially planar and the second apex region sidewall is substantially planar.

3. The structure of claim 1, wherein the first apex region sidewall is substantially non-planar and the second apex region sidewall is substantially non-planar.

4. The structure of claim 1, wherein the RSD is configured to, based on a voltage applied across the bottom conductive electrode and the top conductive electrode, form filaments in the filament region.

5. The structure of claim 4, wherein more than one half of the filaments formed in the filament region are formed in the apex region.

6. The structure of claim 1, wherein the filament region comprises a metal oxide.

7. The structure of claim 6, wherein the metal oxide comprises a compound selected from the group consisting of HfO₂, Ta₂O₅, and ZrO₂.

8. The structure of claim 1, wherein the insulator region further comprises a reactive electrode.

9. An integrated circuit (IC) structure comprising:
a resistive switching device (RSD) comprising:
a bottom conductive electrode, wherein a portion of the bottom conductive electrode is within a via formed in a fill material of the IC structure;
an insulator region communicatively coupled to the bottom conductive electrode, wherein the insulator region comprises a filament region; and
a top conductive electrode communicatively coupled to the insulator region;
wherein the filament region comprises an apex region comprising a first apex region sidewall and a second apex region sidewall;
wherein the second apex region sidewall intersects the first apex region sidewall at an angle that is less than about 90 degrees; and
wherein at least a portion of the apex region is over the via.

10. The structure of claim 9, wherein the first apex region sidewall is substantially planar and the second apex region sidewall is substantially planar.

11. The structure of claim 9, wherein the first apex region sidewall is substantially non-planar and the second apex region sidewall is substantially non-planar.

12. The structure of claim 9, wherein the RSD is configured to, based on a voltage applied across the bottom conductive electrode and the top conductive electrode, form filaments in the filament region.

13. The structure of claim 9, wherein more than one half of the filaments formed in the filament region are formed in the apex region.

14. The structure of claim 9, wherein the filament region comprises a metal oxide.

15. The structure of claim 14, wherein the metal oxide comprises a compound selected from the group consisting of HfO₂, Ta₂O₅, and ZrO₂.

16. The structure of claim 9, wherein the insulator region further comprises a reactive electrode.

17. A method of forming an integrated circuit structure, the method comprising:
forming a resistive switching device (RSD) by:
forming a bottom conductive electrode;
forming an insulator region communicatively coupled to the bottom conductive electrode, wherein the insulator region comprises a filament region; and
forming a top conductive electrode communicatively coupled to the insulator region;
wherein forming the insulator region comprises forming the filament region to comprise an apex region comprising a first apex region sidewall and a second apex region sidewall; and
wherein the second apex region sidewall intersects the first apex region sidewall at an angle that is less than about 90 degrees.

18. The method of claim 17, wherein:
forming the insulator region comprises forming the insulator region on a top surface of the bottom conductive electrode; and
the top surface of the bottom conductive electrode functions as a template for the first apex region sidewall and the second apex region sidewall.

19. The method of claim 17, wherein the first apex region sidewall is substantially non-planar and the second apex region sidewall is substantially non-planar.

20. The method of claim 17, wherein:
the RSD is configured to, based on a voltage applied across the bottom conductive electrode and the top conductive electrode, form filaments in the filament region;
more than one half of the filaments formed in the filament region are formed in the apex region.
